(19) United States
(12) Patent Application Publication
(10) Pub. No.: US 2010/0013109 A1
(43) Pub. Date: Jan. 21, 2010

(54) FINE PITCH BOND PAD STRUCTURE

(75) Inventor: Ker-Min Chen, Hsinchu City (TW)

Correspondence Address: K&L Gates LLP;IP Docketing, 630 Hansen Way, Palo Alto, CA, 94304, US

(73) Assignee: Taiwan Semiconductor Manufacturing Co., Ltd.

(21) Appl. No.: 12/176,602

(22) Filed: Jul. 21, 2008

(51) Int. Cl. H01L 23/52

(52) U.S. Cl. 257/786; 257/E23.141

(57) ABSTRACT

This invention discloses an integrated circuit (IC) chip which comprises a first, second and third bonding pad connected exclusively to a first, second and third probing pad, respectively, wherein the first bonding pad, the second probing pad and the third bonding pad are substantially aligned linearly with the second probing pad being placed between the first and third bonding pad.

### BACKGROUND

The present invention relates generally to integrated circuit design, and, more particularly, to bond pad structure in the IC design.

A semiconductor IC chip communicates with the outside world through various bonding pads, such as signal bonding pads, and power/ground (P/G) bonding pads. Besides bonding pads, modern IC chips also have probe pads connected to corresponding bonding pads. The probe pads are used for probe pins to make contacts with the IC chip during a wafer level test. FIGS. 1A and 2B are top views of two adjacent pads in a conventional layout. The pads comprise bonding pads 102[0:1], probe pads 104[0:1] and aluminum pads 100[0:1] beneath both the bonding pads 102[0:1] and the probe pads 104[0:1]. Referring to FIG. 1A, during a wafer level test, two probe tip 110[0:1] are in contact with the probe pads 104[0:1], respectively. When a die passes the wafer test, it can be packaged into a final product. In a packaging process, a wire is welded, in one hand, to a lead, and in the other hand, to a bonding pad. Referring to FIG. 1B, wires 124[0:1] are welded to the bonding pads 102[0:1], respectively, at welding spots 122[0:1].

A challenge modern IC manufacture faces is the transistor sizes keep shrinking rapidly, and more and more number of pads are needed in an IC chip, but spacing between bonding wires as well as spacing between probe pads cannot keep up with the transistor's pace of shrinking. As such, what is desired is a pad layout arrangement that can extend the spacing between bonding pads and the spacing between probe pads without increase overall area occupied by the bonding pads and the probe pads.

### SUMMARY

This invention discloses an integrated circuit (IC) chip which comprises a first, second and third bonding pad connected exclusively to a first, second and third probing pad, respectively, wherein the first bonding pad, the second probing pad and the third bonding pad are substantially aligned linearly with the second probing pad being placed between the first and third bonding pad. Additionally, the first probing pad, the second bonding pad and the third probing pad are substantially aligned linearly with the second bonding pad being placed between the first and third probing pad.

The construction and method of operation of the invention, however, together with additional objectives and advantages thereof will be best understood from the following description of specific embodiments when read in connection with the accompanying drawings.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting, embodiments illustrated in the drawings, wherein like reference numbers (if they occur in more than one view) designate the same elements. The invention may be better understood by reference to one or more of these drawings in combination with the description presented herein.

FIGS. 1A and 2B are top views of two adjacent pads in a conventional layout.

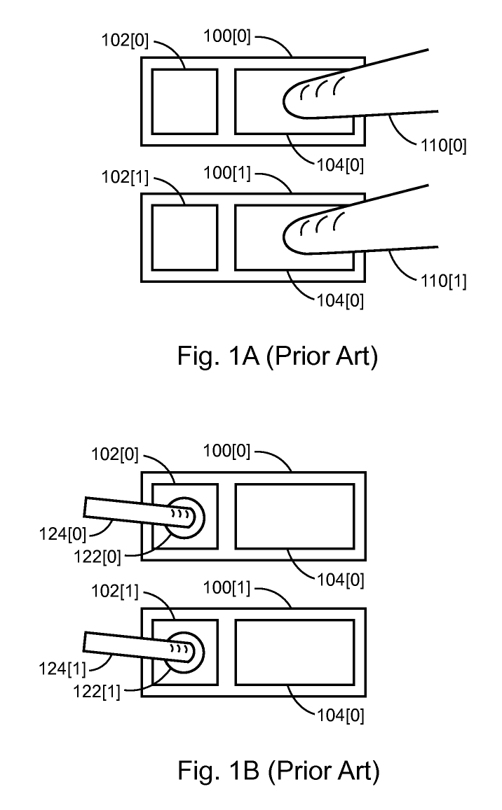

FIG. 2 is a top view of three pairs of adjacent pads arranged according to one embodiment of the present invention.

FIGS. 3A and 3B are cross-sectional views of pad structures as illustrated in FIG. 2.

### DESCRIPTION

The present invention discloses a pad layout arrangement with bonding pads and probing pads alternately placed in a substantially straight line, so that the spacing between two bonding pads in the substantially straight line direction is two pitches, so is the spacing between two probing pads in the substantially straight line. Here a pitch is the distance between the centers of two adjacent pads.

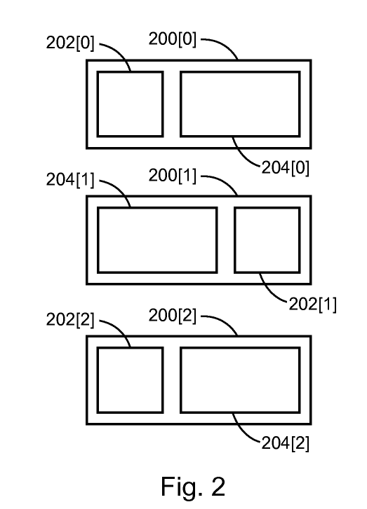

FIG. 2 is a top view of three pairs of adjacent pads arranged according to one embodiment of the present invention. Each pair of pads has a bonding pad 202 and a probing pad 204. The bonding pad 202 and probing pad 204 are connected by an aluminum pad 200. On the aluminum pad 200[0], the bonding pad 202[0] is on the left hand side, and the probing pad 204[0] is on the right hand side. On the aluminum pad 200[1], the probing pad 204[1] is on the left hand side, and the bonding pad 202[1] is on the right hand side. On the aluminum pad 200[2], the bonding pad 202[2] is on the left hand side, and the probing pad 204[2] is on the right hand side. Alternatively, the probing pad 204[1] can be viewed as being placed between two bonding pads 202[0] and 202[2] in a first vertical linear alignment. Therefore, a spacing between the bonding pads 202[0] and 202[2] is two pitches, i.e., one pitch between the bonding pad 202[0] and the probing pad 204[1] plus another pitch between the probing pad 204[1] and the bonding pad 202[2]. In a second vertical linear alignment, the bonding pad 202[1] is placed between the probing pads 204[0] and 204[2]. Therefore, spacing between the probing pads 204[0] and 204[2] is also two pitches, i.e., one pitch between the probing pad 204[0] and the bonding pad 202[1], plus another pitch between the bonding pad 202[1] and the probing pad 204[2]. Here the linear alignment does not necessarily mean that the centers of all the pads are in a straight line. The alignment is considered linear when an extrapolation of the pads substantially resembles a straight line. In fact, since the bonding and probing process are totally unrelated, the probing pad 204[1] does not need to straightly align with either the bonding 202[0] or the bonding pad 202[2]. Similarly the bonding pad 202[1] does not need to straightly align with either the probing pad 204[0] or the probing pad 204[2]. Typically, the bonding pads 202[0] and 202[2] are placed in a straight line, and probing pad 204[0] and 204[2] are placed in a straight line, too. An essence of the present invention is to alternately placing bonding pads and probing pads so that the spacing between two bonding pads or two probing pads is two pitches instead of one pitch as in conventional pad layout.

Referring again to FIG. 2, the bonding pads 202[0] and 202[1] or the probing pads 204[0] and 204[1] may be less than two pitches depending on how far the bonding pad 202 and the probing pad 204 on the same aluminum pad 200 are placed. When the bonding pad 202 and probing pad 204 on the same aluminum pad 200 are place far apart, the bonding pads 202 are essentially placed in two columns with at least two pitches of spacing, and the probing pads 204 are also essentially placed in two columns with at least two pitches of spacing. Since devices or routings can still be formed underneath the aluminum pads 200, and particularly, the probing pads 204 do not require additional metal layers underneath the aluminum pads 200 for better adherence, spacing far apart the bonding pad 202 and the probing pad 204 of the same aluminum pad 200 may not increase the die size.

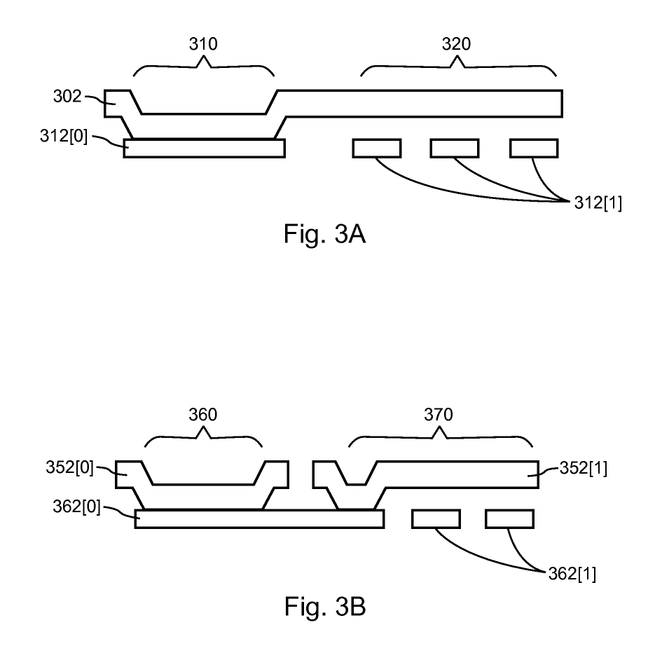

FIGS. 3A and 3B are cross-sectional views of pad structures as illustrated in FIG. 2. Referring to FIG. 3A, an aluminum pad layer 302 is where a probing pin or a bonding wire lands and make a contact to the chip. Regions 310 and 320 represent bonding and probing pads, respectively. The aluminum pad layer 302 is extended continuously from the bonding pad region 310 to the probing pad region 320. A metal layer 312 is placed underneath the aluminum pad layer 302 and making contact thereto in the bonding pad region 310. Then the metal layer 312 is connected to the rest of the chip through vias and other metal layers (both not shown). The same metal layer 312[1] underneath the probing pad region 320 is not required to make contact with the aluminum pad layer 302, therefore, the metal layer 312[1] can be used for metal routing underneath the probing pad region 320.

Referring to FIG. 3B, an aluminum pad layer 352 has two regions 352[0] and 352[1] for a bonding pad region 360 and a probing pad region 370, respectively. The aluminum pad layer 352 is not continuous from the bonding pad region 360 and the probing pad region 370. Instead a connection between the bonding pad region 360 and the probing pad region 370 is made through a metal layer 362[0] which is continuous and contacted by both the bonding pad aluminum layer 352[0] and the probing pad aluminum layer 352[1]. The structure shown in FIG. 3B is often used when the bonding pad region 360 is relatively far away from the probing pad region 370. When there are still rooms underneath the probing pad aluminum layer 352[1], a metal layer 362[1] can be routed thereunder. The metal layers 362[0] and 362[1] belong to the same metal layer.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. An integrated circuit (IC) chip comprising a first, second and third bonding pad connected exclusively to a first, second and third probing pad, respectively, wherein the first bonding pad, the second probing pad and the third bonding pad are substantially aligned linearly with the second probing pad being placed between the first and third bonding pad.

2. The IC chip of claim 1, wherein the first, second and third bonding pad and the first, second and third probing pad comprises a metal pad layer.

3. The IC chip of claim 2, wherein the metal pad layer is an aluminum layer.

4. The IC chip of claim 2, the first bonding pad and the first probing pad are connected by the metal pad layer.

5. The IC chip of claim 1 further comprising at least one interconnect metal layer deposited underneath the pad layer.

6. The IC chip of claim 5, wherein the first bonding pad and the first probing pad are connected by the at least one interconnect metal layer.

7. The IC chip of claim 5 further comprising at least one via connecting the pad layer and the at least one interconnect metal layer.

8. The IC chip of claim 1, wherein the first probing pad, the second bonding pad and the third probing pad are substantially aligned linearly with the second bonding pad being placed between the first and third probing pad.

9. An integrated circuit (IC) chip comprising a first, second and third bonding pad connected exclusively to a first, second and third probing pad, respectively, wherein the first bonding pad, the second probing pad and the third bonding pad are substantially aligned linearly with the second probing pad being placed between the first and third bonding pad, and the first probing pad, the second bonding pad and the third probing pad are substantially aligned linearly with the second bonding pad being placed between the first and third probing pad.

10. The IC chip of claim 9, wherein the first, second and third bonding pad and the first, second and third probing pad comprises a metal pad layer.

11. The IC chip of claim 10, wherein the metal pad layer is an aluminum layer.

12. The IC chip of claim 10, the first bonding pad and the first probing pad are connected by the metal pad layer.

13. The IC chip of claim 9 further comprising at least one interconnect metal layer deposited underneath the pad layer.

14. The IC chip of claim 13, wherein the first bonding pad and the first probing pad are connected by the at least one interconnect metal layer.

15. The IC chip of claim 13 further comprising at least one via connecting the pad layer and the at least one interconnect metal layer.

16. An integrated circuit (IC) chip comprising a first, second and third bonding pad connected exclusively to a first, second and third probing pad, respectively, through a metal pad layer, wherein the first bonding pad, the second probing pad and the third bonding pad are substantially aligned linearly with the second probing pad being placed between the first and third bonding pad.

17. The IC chip of claim 16 further comprising at least one interconnect metal layer deposited underneath the metal pad layer.

18. The IC chip of claim 17 further comprising at least one via connecting the metal pad layer and the at least one interconnect metal layer.

19. The IC chip of claim 16, wherein the first probing pad, the second bonding pad and the third probing pad are substantially aligned linearly with the second bonding pad being placed between the first and third probing pad.
